(19) United States
(12) Patent Application Publication
(10) Pub. No.: US 2025/0008707 A1
(43) Pub. Date: Jan. 2, 2025

(54) MANAGING AIR CIRCULATION IN A COMPACT ELECTRONIC DEVICE

(71) Applicant: PLUME DESIGN, INC., Palo Alto, CA (US)

(72) Inventors: Ming-Tsung SU, Taipei City (TW); Chun-Wen WANG, Taoyuan City (TW); Yu-Ting HUANG, Hsinchu City (TW); Chun-Hung LIU, Taipei City (TW); Meng-Jung CHUANG, Taipei City (TW)

(21) Appl. No.: 18/757,919

(22) Filed: Jun. 28, 2024

Related U.S. Application Data
(60) Provisional application No. 63/511,273, filed on Jun. 30, 2023.

(51) Int. Cl. H05K 7/20

(52) U.S. Cl. CPC H05K 7/20909; H05K 7/20154

(57) ABSTRACT

Disclosed is a compact electronic device configured to efficiently manage air circulation and prevent overheating. The device features an innovative cooling system comprising a fan module within a uniquely structured housing that includes a base portion, an inner casing, and a removable top cover. The inner casing features strategically placed windows that direct drawn airflow over specific power supply components, enhancing cooling performance. The enhanced cooling is also provided by an air gap formed between the base portion and the top cover, as well as sidewall intake paths of varying widths adjacent the windows. These features work together to draw in and distribute ambient air effectively across heat-generating components, leveraging negative pressure created by a fan module. The result is a highly efficient cooling mechanism for compact devices such as wireless access point configured to plug into electrical outlets.

### CROSS-REFERENCE TO RELATED APPLICATIONS

This application claims the benefit of priority from U.S. Provisional Patent Application No. 63/511,273, which was filed on Jun. 30, 2023, which is incorporated herein by reference in its entirety.

### FIELD OF THE DISCLOSURE

The present disclosure generally relates to a wireless networking device. More particularly, the present disclosure relates to systems and methods for cooling a compact electronic device, such as a wireless access device.

### SUMMARY

Wi-Fi networks, also known as Wireless Local Area Networks (WLAN), are now prevalent in almost all settings. People use them at home, at work, and in public places like schools, cafes, and parks. Wi-Fi offers great convenience by eliminating cables and allowing for mobility. The range of applications running over Wi-Fi keeps expanding, with current uses including video streaming, audio streaming, phone calls, video conferencing, online gaming, and security camera feeds. Additionally, traditional data services such as web browsing, file transfers, disk backups, and numerous mobile apps are often used simultaneously. Wi-Fi has become the primary means of connecting user devices to the Internet in homes and other locations, with the majority of connected devices relying on Wi-Fi for network access. Consequently, Wi-Fi access devices, specifically Wi-Fi Access Points (APs), are installed in a distributed manner within a location such as a home or office.

The trend in consumer electronics design favors aesthetically pleasing, compact hardware. For example, a distributed Wi-Fi system comprises several Wi-Fi APs placed throughout a location like a residence. However, distributing multiple APs around a house necessitates that these devices be small, attractive, and free from visible, unattractive vent holes, demanding unique industrial design solutions. These small APs with appealing, compact designs present significant challenges regarding cooling and airflow.

As with other technology fields, Wi-Fi has evolved significantly in recent years. For instance, Wi-Fi 5 is being superseded by Wi-Fi 6 (or Wi-Fi 6E), which introduces an additional 6 GHz band and effectively quadruples the number of transmission channels. While Wi-Fi 5 supports speeds of up to 3.5 Gbps, Wi-Fi 6 can reach speeds of 9.6 Gbps. However, these enhancements also have drawbacks. For example, an AP using Wi-Fi 6 technology requires more power. A Wi-Fi 5 AP device might consume around 15 W of power, whereas a Wi-Fi 6 AP device might consume 24 W, resulting in increased heat generation and potential overheating without adequate ventilation. Therefore, there is a need to develop a fan module within the same form factor as previous generations that can more efficiently move air through the AP to prevent overheating, even at higher power levels.

To that end, according to some embodiments, the disclosed system includes a compact electronic device that functions as a wireless Access Point (AP). In some embodiments, the AP includes a housing with multiple sides adjacent to a base portion. The base houses various components including a fan module, a Printed Circuit Board (PCB) with one or more Wi-Fi radios, and/or a power supply. The AP also features an electrical plug connected to the power supply, extending from the bottom for insertion into an electrical outlet, providing both power and physical support for the AP. Additionally, the AP includes multiple vents hidden from view when the device is plugged into the outlet.

In some embodiments, a compact electronic device features an outer plastic housing and an inner casing. The system contains components that support both higher and lower voltage operations within a single structure. In some embodiments, the system includes a single fan designed to draw air from outside the housing and expel it through exhaust vents in the housing. The inner casing is designed to isolate specific electrical components from metal parts to meet safety standards. In some embodiments, the inner casing includes a first window and a second window configured to direct air being drawn by the vacuum created by the single fan. In some embodiments, the fan module is configured to create a vacuum to draw air through one or more intakes in the housing. In some embodiments, the first window is configured to direct a first portion of the drawn air in a first direction over a first power supply component. In some embodiments the second window is configured to direct a second portion of the drawn air in a second direction over a second power supply component. In some embodiments, the system further includes a third window, where the third window is configured to direct a portion of the drawn air in a third direction over a third power supply component. In some embodiments, the power supply is electrically connected to an AC electrical plug extending from a base portion of the housing.

Moreover, this compact electronic device supports various modules, including a fan module with at least a single fan, and components connected to an AC electrical plug that provides power and physical stability when plugged into an outlet. A plastic chamber within the inner casing protects electrical components from electromagnetic interference. The chamber features side windows allowing air to flow from bottom vents through the inner casing and the chamber. In some embodiments, the system includes three side windows strategically placed to enhance cooling while maintaining electromagnetic separation.

In some embodiments, the housing comprises a continuous gap that is configured as both an air intake and an air exhaust. In some embodiments, the housing comprises a removable top cover attached to a base, forming slit vents with a predetermined gap that allow air to flow into the housing. The top cover is configured to couple to the base, and the top cover and the base are configured to surround the inner casing.

The top cover has a downward-extending wall that hides the inner casing and components from view. In some embodiments, an insert with top, side, and slanted bottom surfaces attaches to the underside of the top cover, directing airflow smoothly and reducing turbulence. Portions of the insert fill gaps formed by connection elements attaching the top cover to the base, enhancing airflow and reducing turbulence. In some embodiments, the gap between the top cover and the base include multiple intake air vents and one exhaust air vent, with the bottom section featuring additional intake vents. An additional exhaust vent under the gap exhaust vent increases airflow out of the AP.

In some embodiments, coupled to the inner casing are a middle heat spreader and a bottom heat spreader. The first window, in some embodiments is a different size than the second window, where the different size is configured to create an airflow in a gap between the middle heat spreader and the bottom heat spreader. In some embodiments, the heat sink comprises a plurality of sink fins. In some embodiments, one or more of the plurality of sink fins include a fin aperture configured to enable drawn air to pass through. In some embodiments, the fan module is coupled to a center portion of the heat sink. Windows formed between and/or with the bottom heat spreader and/or middle heat spreader direct drawn air to different sides of the heat sink, which are distal from the center portion.

In some embodiments, a first sidewall intake path is formed adjacent the first window, and a second sidewall intake path is formed adjacent the second window. In some embodiments, the first sidewall intake path and the second sidewall intake path are configured to direct the drawn air toward the top cover. In some embodiments, the heat sink is adjacent the top cover, and the first sidewall intake path and the second sidewall intake path are configured to direct the drawn air over an outer parameter of the heat sink. In some embodiments, the heat sink includes a fan aperture configured to enable drawn air to pass from below the heat sink into the fan module.

### DESCRIPTIONS OF THE DRAWINGS

The features, and advantages of the disclosure will be apparent from the following description of embodiments as illustrated in the accompanying drawings, in which reference characters refer to the same parts throughout the various views. The drawings are not necessarily to scale, emphasis instead being placed upon illustrating principles of the disclosure:

FIG. 1 shows a compact electronic device configured to be plugged into an electrical outlet according to some embodiments of the present disclosure;

FIG. 2 illustrates a perspective view of the compact electronic device according to some embodiments of the present disclosure;

FIG. 3 shows air intake paths through an air gap according to some embodiments of the present disclosure;

FIG. 4 depicts internal features of the system according to some embodiments of the present disclosure;

FIG. 5 shows air flow through internal portions of the system according to some embodiments of the present disclosure;

FIG. 6 illustrates features of the fan module and heat sink according to some embodiments of the present disclosure;

FIG. 7 shows various apertures in the heat sink according to some embodiments of the present disclosure;

FIG. 8 shows an airflow simulation according to some embodiments of the present disclosure;

FIG. 9 illustrates another airflow simulation according to some embodiments of the present disclosure;

FIG. 10 shows a simplified view of a portion of the airflow from FIG. 8 according to some embodiments of the present disclosure;

FIG. 11 shows the direction airflow caused by windows within the inner casing according to some embodiments of the present disclosure;

FIG. 12 illustrates details of three windows according to some embodiments of the present disclosure; and

FIG. 13 shows an air simulation through the three windows according to some embodiments of the present disclosure.

### DETAILED DESCRIPTION

This disclosure pertains to systems and methods for cooling compact electronic devices, such as wireless access devices. These devices, which can include Wi-Fi Access Points (APs) in distributed Wi-Fi systems, feature a small form factor with multiple sides, direct plug-in capability to an electrical outlet, and internal components such as a power supply and fan. To accommodate this compact design, the device incorporates a unique form factor and airflow layout, an air gap structure utilizing the same openings for both intake and exhaust, a layered structure for directing airflow between layers, and an interior fan. This design ensures efficient cooling through multiple air intake points, quiet operation due to the internal fan module, long lifespan, low cost, and compact size.

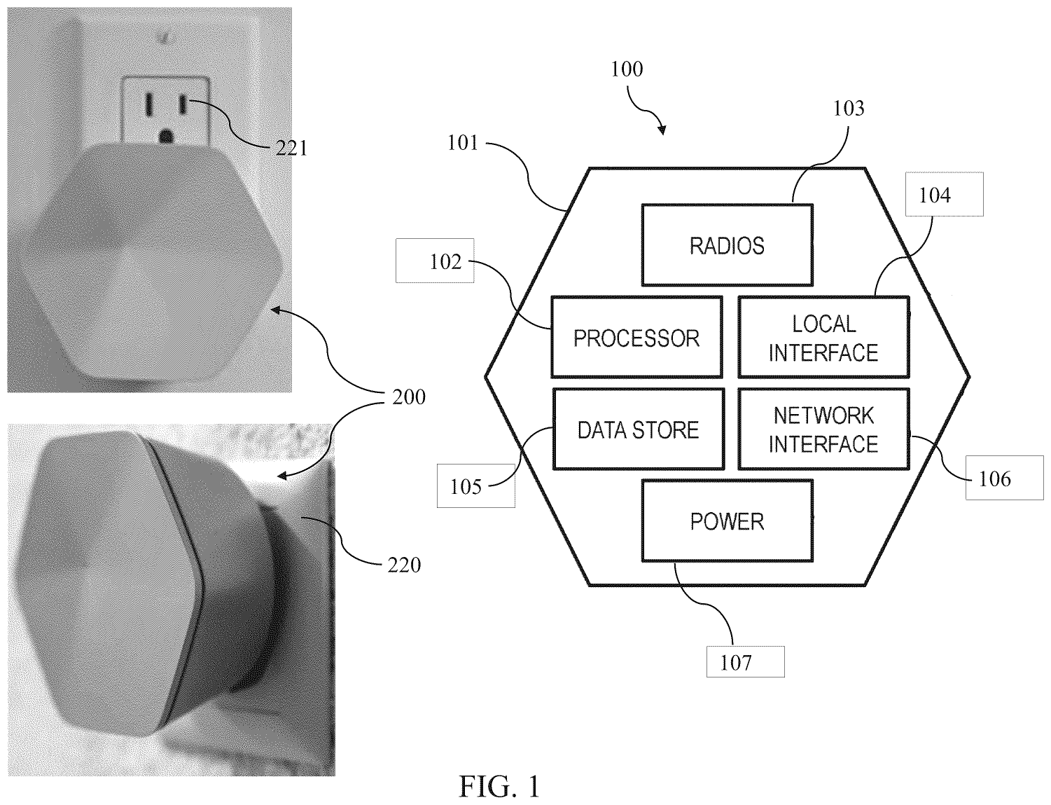

Referring to the figures, various illustrations depict a compact electronic device 100 for illustration purposes. In some embodiments, this device functions as a wireless Access Point (AP) 200 or equivalent wireless access device. As shown in FIG. 1 the AP 200 features a compact form factor 101 that allows it to be plugged directly into an electrical outlet 220. In some embodiments, the size of the AP is compact, meaning the AP is configured to not obstruct other outlets, and/or is weighted to be supported by the outlet 220 and/or plug 221. While described herein as a wireless access point 200, it is understood that the systems and methods described here can be applied to any type of electronic device, including sensors, cameras, Internet of Things (IoT) devices, media players, and digital assistants, as non-limiting examples.

In some embodiments, the physical form factor 101 includes a processor 102, multiple radios 1023, a local interface 104, a data store 105, a network interface 106, and/or a power supply 107. This diagram simplifies the compact electronic device 100, and some embodiment may have additional components and processing logic to support the described features or conventional operating features not detailed here.

In some embodiments, the form factor 101 is ideal for distributing many access points throughout a residence. The processor 102 executes software instructions and can be a custom or commercially available CPU, a semiconductor-based microprocessor, a chipset, and/or any device for executing software instructions. When operational, the processor 102 executes software stored in memory or the data store 105, communicates data to and from these storage elements, and generally controls the access point's operations. The processor 102 may be optimized for power consumption and mobile applications.

In some embodiments, the radios 103 enable wireless communication, operating according to the IEEE 802.11 standard, for example, and includes connections for communications on a Wi-Fi system. The access point 200 can support multiple radios for different links, such as backhaul and client links. Some embodiments supports dual-band operation with 2.4 GHz and 5 GHZ 2×2 MIMO 802.11b/g/n/ac radios, providing operating bandwidths of 20/40 MHz for 2.4 GHz and 20/40/80 MHz for 5 GHz. The access points may support IEEE 802.11AC1200 gigabit Wi-Fi.

The local interface 106 enables local communication with the access point 200, either wired or wirelessly (e.g., Bluetooth®). The data store 105 stores data and may include volatile memory (e.g., RAM), nonvolatile memory (e.g., ROM, hard drive, CDROM), or combinations thereof, incorporating various types of storage media.

The network interface 106 provides wired connectivity, such as the RJ-45 ports 205, enabling communication with a modem/router and local connectivity to Wi-Fi client devices. This can provide network access to devices without Wi-Fi support. The network interface 106 may include an Ethernet card or adapter, with connections for appropriate network communications. The processor 102 and the data store 106 may include software and/or firmware controlling the access point's operation, data management, and/or memory management.

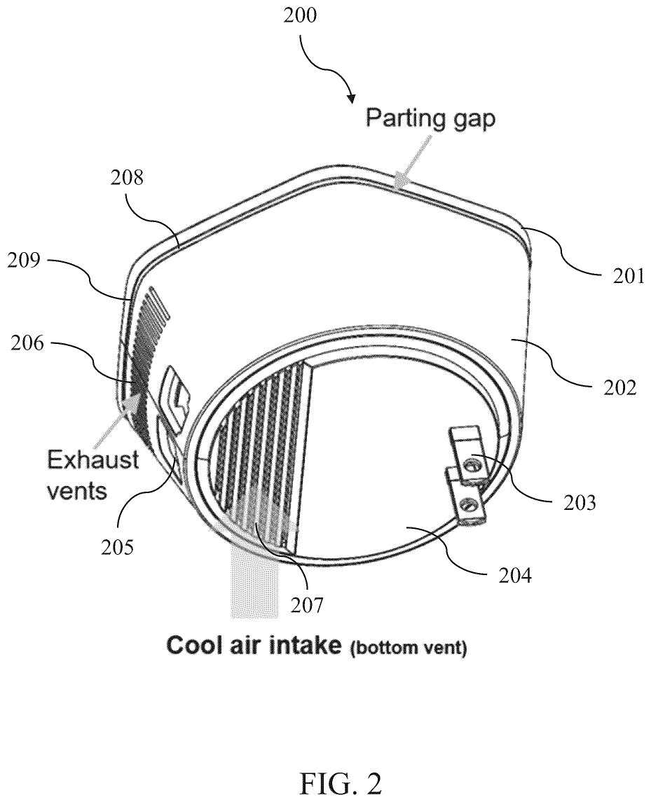

As shown in FIG. 2, the AP 200 includes a top cover 201 over a base 202 and an electrical plug 203 protruding from the bottom portion 204 of the base 202. The base 202 includes RJ-45 ports 205 for data connectivity, such as via Ethernet cables. The base 202 may also include other types of wired ports, which are not illustrated. Additionally, the base 202 features various openings for air intake and exhaust, including an exhaust vent(s) 206 on a side of the base 202, an intake vent(s) 207 on the bottom portion 204, and an air gap 208 between the top cover 201 and the base 202.

The exhaust vent 206 and intake vent 207) are configured to be hidden when the compact electronic device 100 is plugged into an electrical outlet (see FIG. 1). That is, these openings are not observable by someone looking at the device when it is plugged in. Multiple openings for air intake allow cooler air to reach the components near the respective vents as further described below.

The electrical plug 203 serves dual functions: providing electrical connectivity to a corresponding outlet and mechanically supporting the compact electronic device 100 while it is plugged in. In some embodiments, the bottom portion 204 is configured to be positioned adjacent to a structure (e.g., a wall) with an electrical outlet. In some embodiments, the intake vent 207 is recessed from the bottom portion 204 to create an airflow gap when the bottom portion is in contact with the outlet 220.

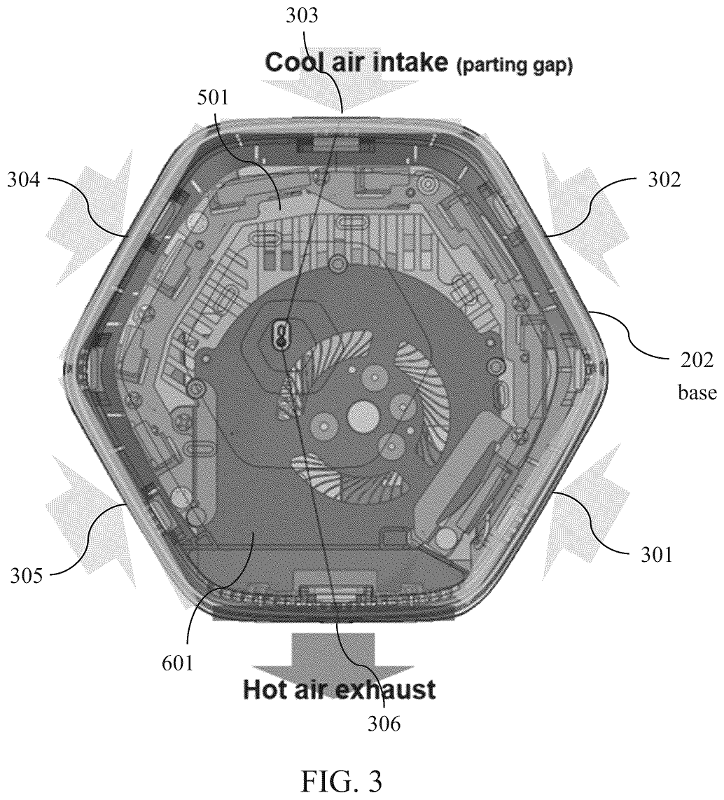

As shown in FIG. 3, the base 202 can have a plurality of sides 301, 302, 303, 304, 305, and 306. In some embodiments, the form factor 101 shown includes a hexagonal perimeter, i.e., six sides, but other configurations are possible. In some embodiments, the compact electronic device 100 utilizes a plurality of different sides for air intake. FIG. 3 also illustrates the airflow, with air intake (cold or room temperature air) shown at sides 301, 302, 303, 304, and 305, and air exhaust (warm air) at side 306.

In some embodiments, the exhaust vent 206 and the air gap exhaust 209 on side 306 are used for hot air exhaust, while the intake vent 207, as well as the air gap 208 on sides 301, 302, 303, 304, and 305, are used for cold (i.e., ambient) air intake. A heat sink 501 and/or the fan module 601 is configured to cooperate with one or more protrusions 401 extending from the top cover 201 separate the air intake and exhaust portions of the air gap 208.

In some embodiments, the top cover 201 is configured to couple (e.g., snap) onto the base 202, forming the air gap 208 between the top cover 201 and the base 202. In some embodiments, the air gap 208 includes a continuous space (e.g., no interrupting protrusions) about a perimeter of the AP 200 along each side 301-306, and appears decorative or structural, rather than vent-like. In some embodiments, the one or more protrusions 401 divide the air intake and exhaust, with double-walled sections for improved isolation and resistance to air leakage, creating a thermal isolating region between intake (cool air) and exhaust (hot air).

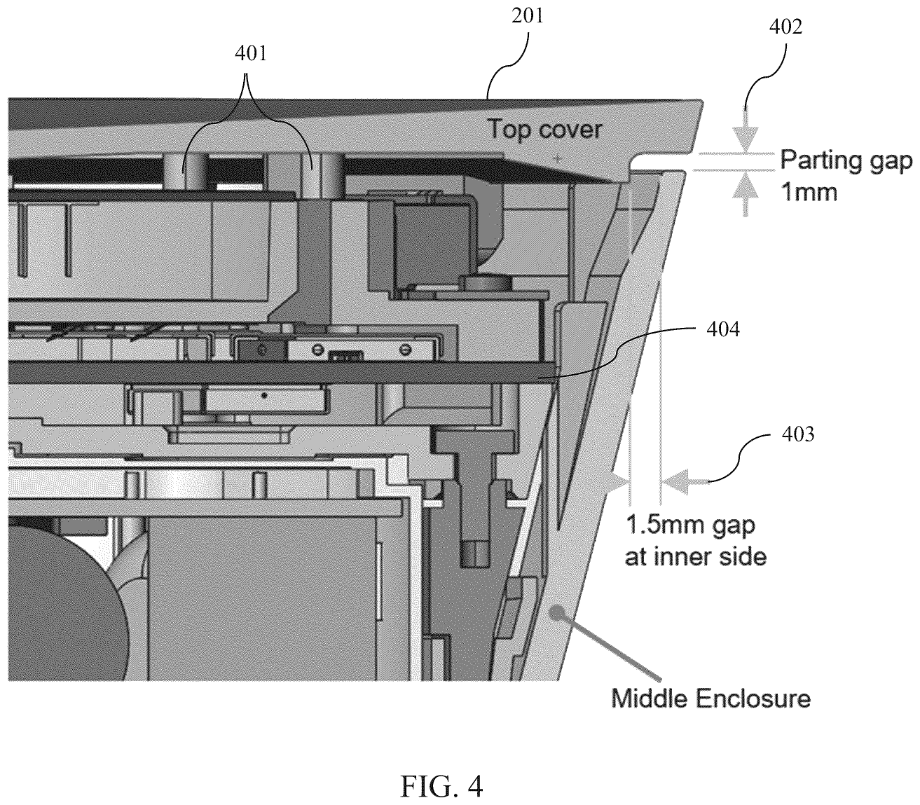

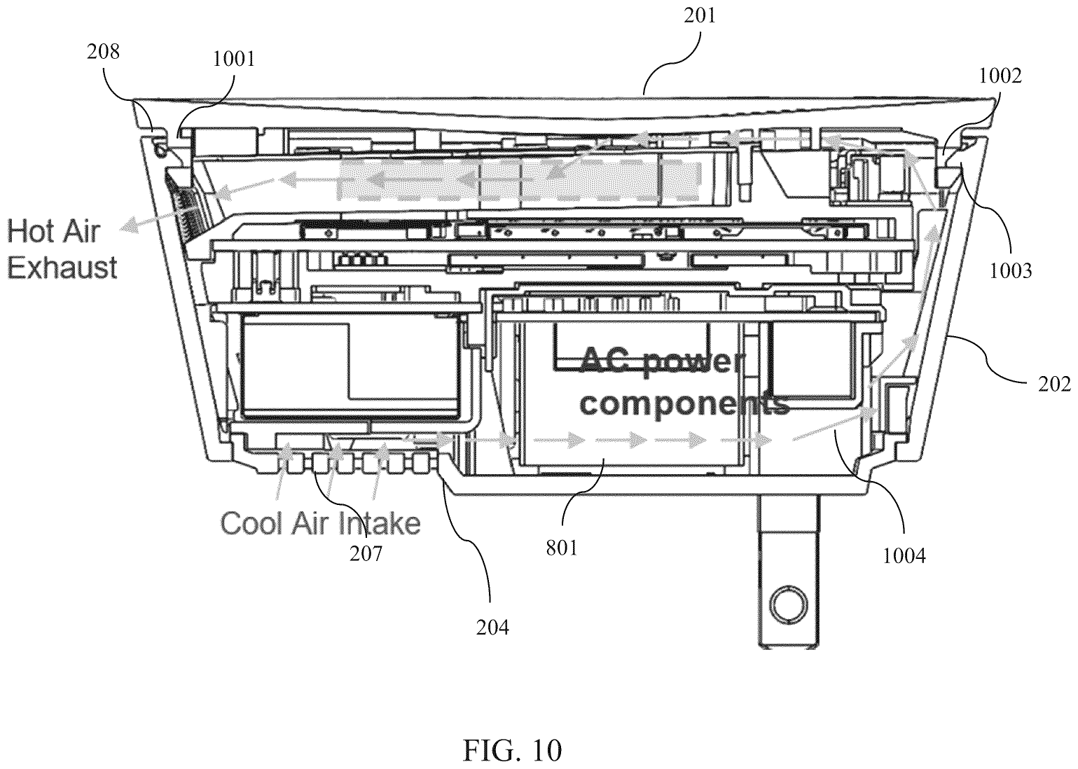

FIG. 4 illustrates the compact electronic device 100 in a cross-section, showing internal components in accordance with some embodiments. With reference to FIG. 10, the top cover 201 is secured in place with the base 202 via protrusions 1001, which may include a tongue and groove mechanism and/or one or more snap fittings as non-limiting examples. Referring back to FIG. 4, the protrusions 1001 are separated and/or recessed from both an air gap outer opening 402 and an air gap inner opening 403 so that the air gap 208 appears continuous when the system is assembled. A power supply 801 powers all components and is connected to the electrical plug 203.

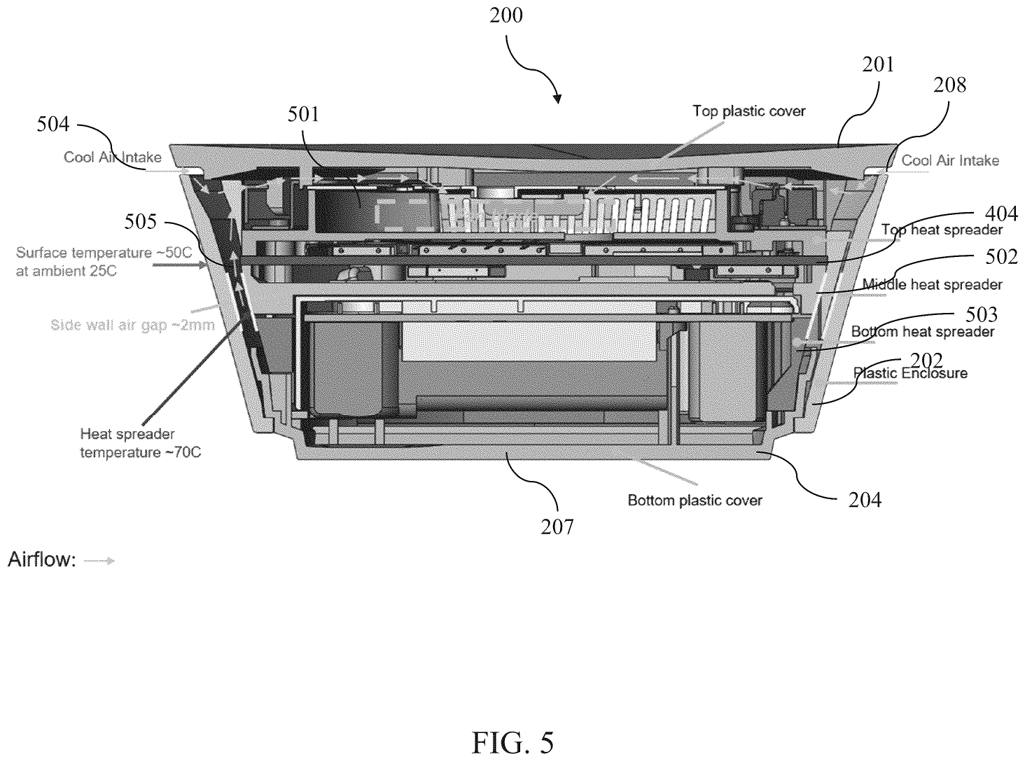

FIG. 5 depicts a cross-sectional view of the AP 200, showing various components and features of the system. In some embodiments, the AP 200 includes one or more of a top cover 201, a heat sink 501, a PCB 404, a middle heat spreader 502, a bottom heat spreader 503, a base 202, and a bottom portion 204. In some embodiments, the PCB 404 contains various heat-generating electronic components, such as Wi-Fi chipsets.

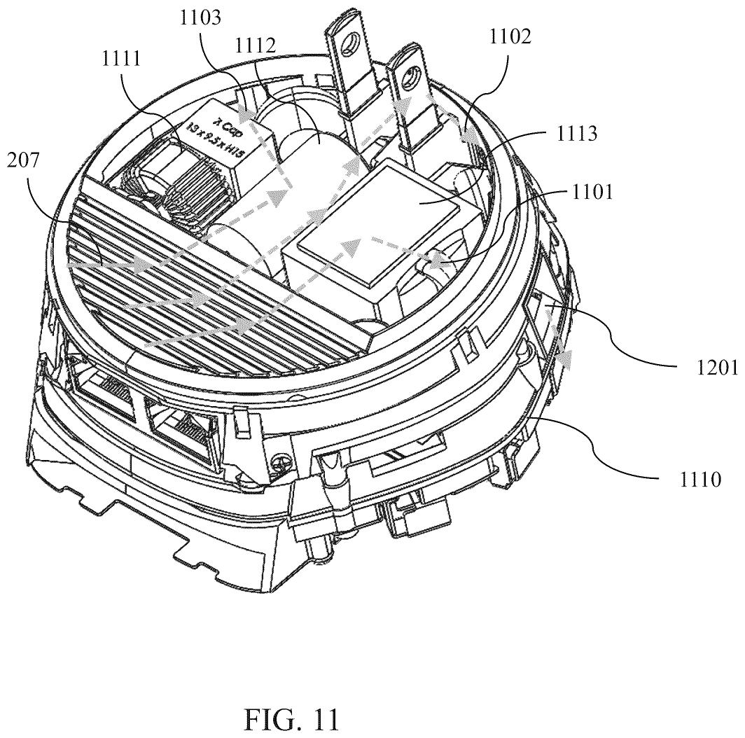

As shown in FIG. 5, cool air is fed through the air gap 208 through the air gap intake path 504, represented by arrows, and a sidewall intake path 505 from which cool air is drawn by vacuum force through intake vent 207. The sidewall intake path 505 is fed by one or more windows 1301, 1302, and/or 1303 discussed further in relation to FIGS. 11-13. In some embodiments, one or more sidewall intake paths 505 range from 1 millimeter (mm) to 4 mm in width, where 2 mm has been found to be effective at maintaining the middle heat spreader temperature below 70° Celsius (C), and/or a surface temperature of the base 202 below 50° C., when ambient air temperature is at or below 25° C. Sidewall intake paths may vary in width to allow more airflow or to restrict airflow such that higher heat producing components receive more air.

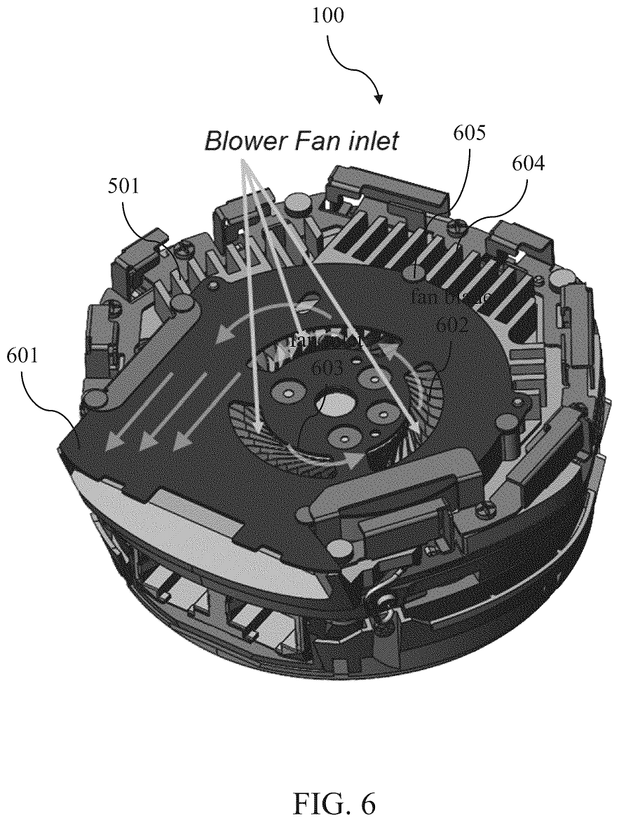

FIG. 6 illustrates the compact electronic device 100 with the top cover 201 and base 202 removed in accordance with some embodiments. Straight arrows indicate airflow toward the exhaust vent 206 and/or air gap exhaust 209; curved arrows show a rotation of fan blades 602, which is configured to draw in air from the air gap 208 and intake vent 207 using the vacuum created at the fan inlet 603. The vacuum created by fan module 601 draws air into the air gap intake 504 and sidewall intake path 505 removing heat from the internal components. The drawn-in air, directed by the one or more windows 1301, 1302, and/or 1303, is mixed with the air from the air gap 208, where it passes over and/or through one or more fins 604. This combined airflow from multiple directions provides a more even transfer of heat from the heat sink 501. In some embodiments, the fan module 601 is configured to be attached to the heat sink 501 via one or more fasteners 605 (e.g., screws). The cold air drawn in from the gap 208 is configured to reduce the temperature of the air coming from intake vent 207 providing greater heat transfer for the heat sink 501, which is configured to remove heat from the CPU components.

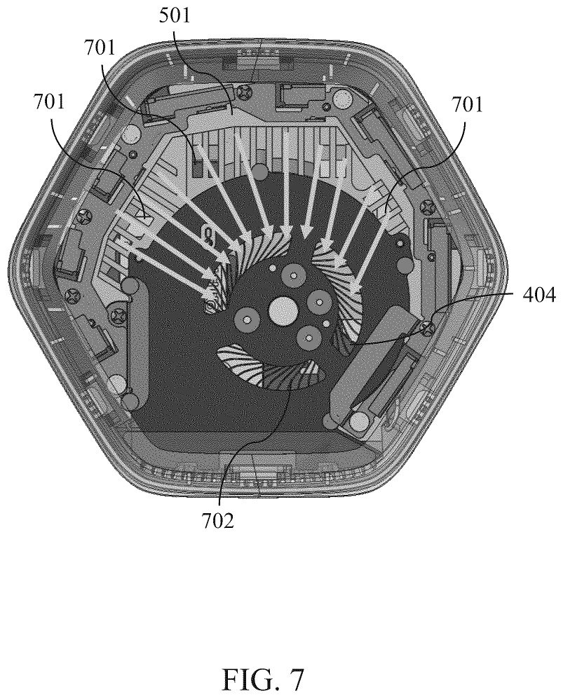

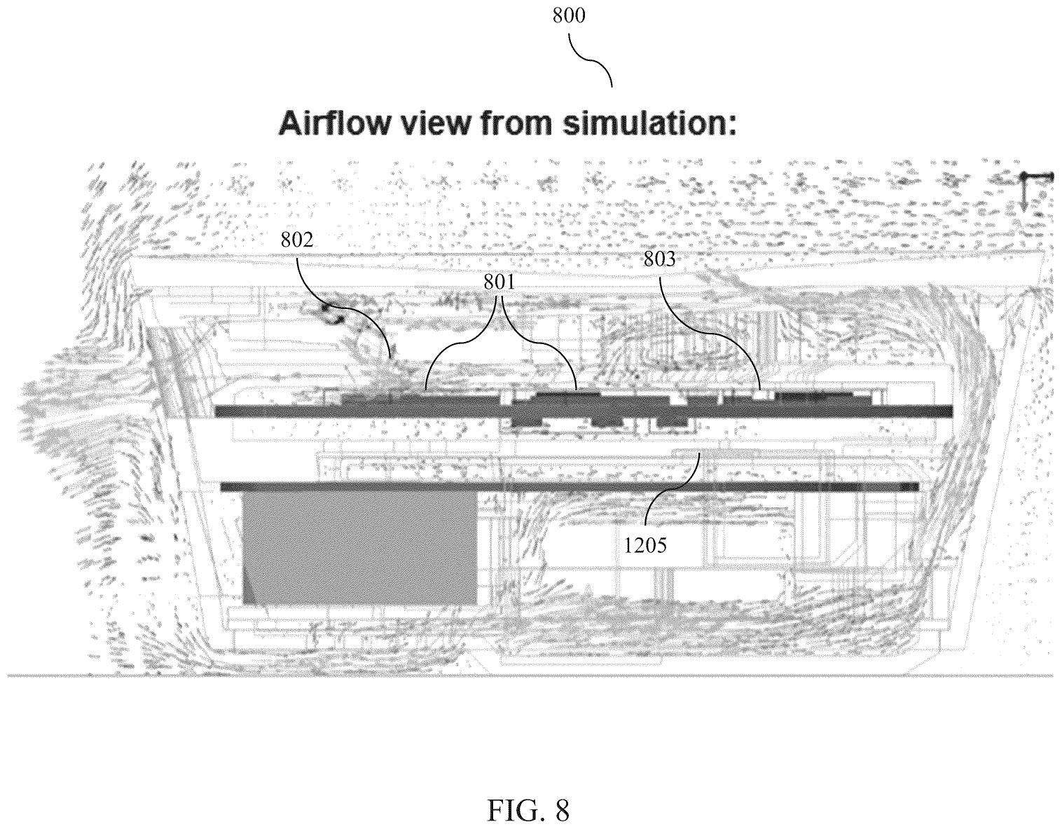

FIG. 7 shows a top view of the heat sink 501 above the PCB 404. The fan module 601 includes fan blades 602 (represented by dashed lines in FIG. 5). In some embodiments, the heat sink includes one or more fin apertures 701 configured to drawn in air from a gap between the PCB 404 and the heat sink 501. In some embodiments, the heat sink 501 includes a fan aperture 702. In some embodiments, the positioning of the fan aperture 702 over the fan blades 602 causes airflow into the PCB gap from a direction defined by each of the one or more windows 1301, 1302, and 1303, further removing heat from one or more CPU components 801 (e.g., chipsets). FIG. 8 shows an airflow simulation 800 with vector arrows showing airflow direction and speed within an internal section of AP 200, including the airflow 802 through fan aperture 702, as well as the PCB gap 803.

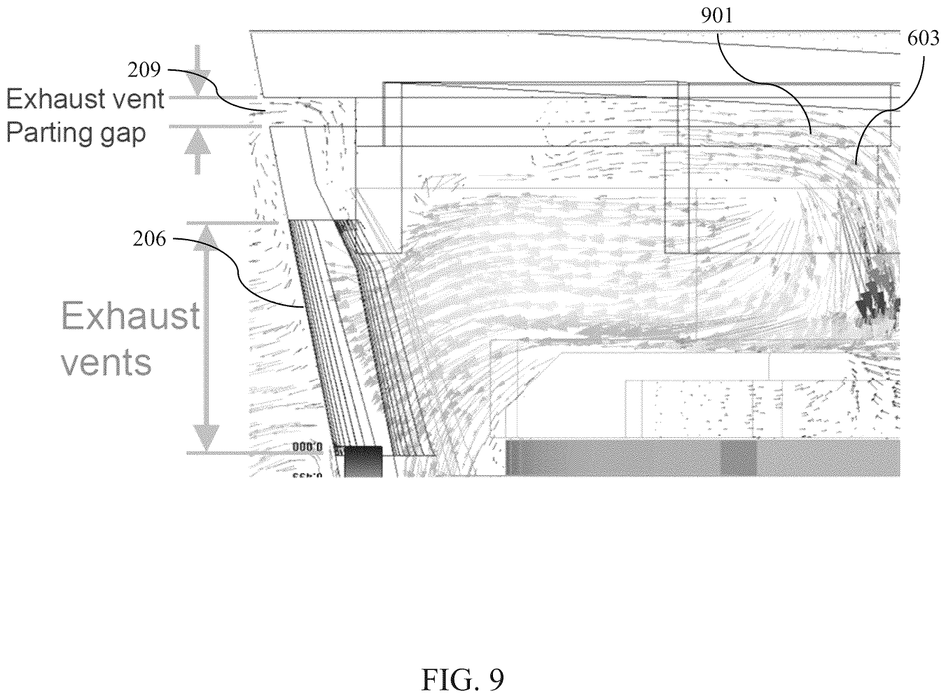

FIG. 9 depicts airflow 901 from a first window 1201 passing through fan inlet 603 and being directed out exhaust vent 206 and air gap exhaust 209. In some embodiments, exhaust vent 206 is between 4 and 10 times the air gap exhaust 209, and therefore most of the air flow through the fan inlet 603 is directed to the exhaust vent 206. However, in response to increase demand, the fan module 601 is configured to increase fan speed, and the air gap exhaust 209 provides an additional path to compensate for the air resistance as more air is forced through the exhaust vent 206.

FIG. 10 illustrates a cross-sectional view of the top cover 201 connected to the base 202, forming the air gap 208. In this non-limiting example, the top cover 201 has one or more top cover protrusions 1002 on one or more sides that snap into corresponding grooves in base protrusion 1003. The air gap 208 is a result of a perimeter of the top cover 201 not being sealed to a perimeter of the base 202; the physical coupling resulting from one or more protrusion 1001 which are recessed from both perimeters. Airflow from the intake vent 207 through the compact electronic device 100, in accordance with some embodiments, is shown with solid arrows 1004, moving from the intake vent 207 on the bottom portion 204, removing heat from the PCB 404, and flowing out of the opening 403 to meet cool air from the air gap 208 and circulate through the fan module 302.

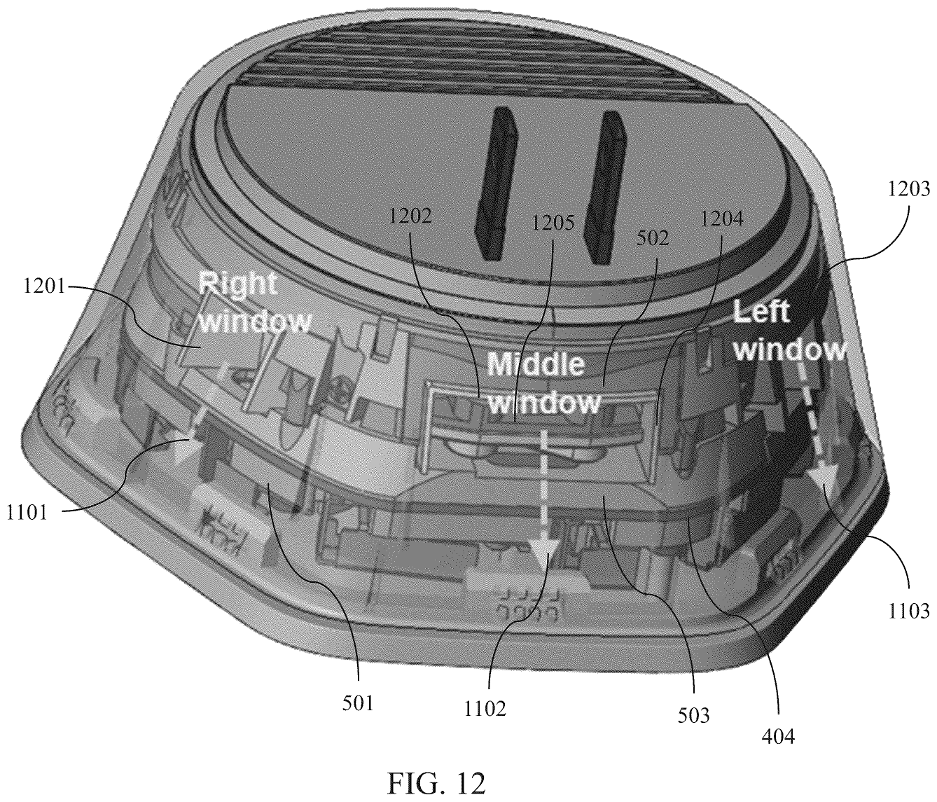

FIG. 11 illustrates an airflow path over the various power supply components 1111, 1112, and 1113, coupled to an inner casing 1110, as well as how the one or more windows (three in this non-limiting example) configured to direct the air flow over different components. In some embodiments, a portion of ambient air entering the intake 207 is pulled in a first direction 1101 over a first power supply component 1111 by the vacuum force at first window 1201, which is the result of the fan module 601 creating a negative vacuum inside AP 200. Without the first window 1201 directing air, first power supply component 1111 may not receive enough airflow to remove sufficient heat to prevent damage to itself or surrounding structures. Similarly, a portion of ambient air entering the intake 207 is pulled in a second direction 1102 over a second power supply component 1112 by the vacuum force at second window 1202 in some embodiments. In some embodiments, a portion of ambient air entering the intake 207 is pulled in a third direction 1103 over a third power supply component 1113 by the vacuum force at second window 1202 in some embodiments. While the non-limiting example in FIG. 12 shows three windows, any number of windows can be used to force air into a specific region within the AP 200.

FIG. 12 shows a perspective view of AP 200 with a first window 1201, a second window 1202, and a third window 1203 arranged in accordance with some embodiments. In some embodiments, one or more window comprise one or more window walls 1204 configured to span between the middle heat spreader 502 and the bottom heat spreader 503. In some embodiments, the sidewalls are configured to enable at least a portion of the airflow to enter a spreader gap 1205. In some embodiments, one or more windows and/or one or more one or more sidewall intake paths are configured to have greater air flow than one or more other windows and/or sidewall intake paths.

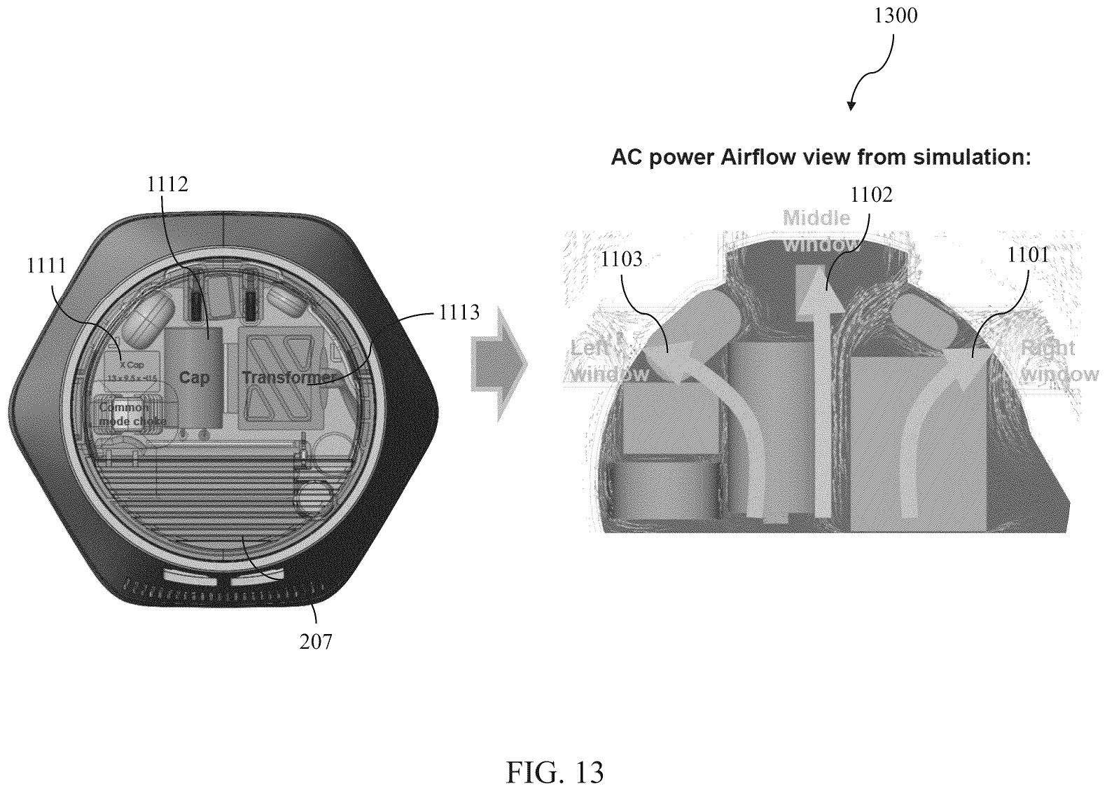

In some embodiments, this difference in flowrate causes a difference in pressure, drawing air from side of AP 200 to another, increasing heat transfer. For example, first window 1201 may be larger than third window 1203, creating a cross-current between the two windows in the heat spreader gap, according to some embodiments. In some embodiments, the sidewall intake path 505 at the second window 1202 may be 4 mm, while a sidewall at the third window 1203 may be 2 mm, resulting in different air velocities and/or a difference in pressure, resulting in cross flow through the gap and/or around the space formed between the internal components of AP 200 and the base 202. FIG. 13, shows a simulation 1300 for airflow over the power supply components 1111, 1112, 1113. In some embodiments, air flow through first window 1201 results in a higher velocity (and lower pressure) than air flow through the third window 1203.

While shown as a compact electronic device 100, it is understood that the system is not limited in its application to the details of construction and the arrangement of components set forth in the previous description or illustrated in the drawings. The system and methods of assembly disclosed herein fall within the scope of numerous embodiments. The previous discussion is presented to enable a person skilled in the art to make and use embodiments of the system. Any portion of the structures and/or principles included in some embodiments can be applied to any and/or all embodiments: it is understood that features from some embodiments presented herein are combinable with other features according to some other embodiments. Thus, some embodiments of the system are not intended to be limited to what is illustrated but are to be accorded the widest scope consistent with all principles and features disclosed herein.

Some embodiments of the system are presented with specific values and/or setpoints. These values and setpoints are not intended to be limiting and are merely examples of a higher configuration versus a lower configuration and are intended as an aid for those of ordinary skill to make and use the system.

Any text in the drawings is part of the system's disclosure and is understood to be readily incorporable into a description of the metes and bounds of the system. Any functional language in the drawings is a reference to the system being configured to perform the recited function, and structures shown or described in the drawings are to be considered as the system comprising the structures recited therein. It is understood that defining the metes and bounds of the system using a description of images in the drawing does not need a corresponding text description in the written specification to fall with the scope of the disclosure.

Furthermore, acting as Applicant's own lexicographer, Applicant imparts the explicit meaning and/or disavow of claim scope to the following terms:

Applicant defines any use of “and/or” such as, for example, “A and/or B,” or “at least one of A and/or B” to mean element A alone, element B alone, or elements A and B together. In addition, a recitation of “at least one of A, B, and C,” a recitation of “at least one of A, B, or C,” or a recitation of “at least one of A, B, or C or any combination thereof” are each defined to mean element A alone, element B alone, element C alone, or any combination of elements A, B and C, such as AB, AC, BC, or ABC, for example.

“Substantially” and “approximately” when used in conjunction with a value encompass a difference of 5% or less of the same unit and/or scale of that being measured (e.g., degrees, volume, mass, distance).

As used herein, “can” or “may” or derivations thereof are used for descriptive purposes only and is understood to be synonymous and/or interchangeable with “configured to” when defining the metes and bounds of the system.

In addition, the term “configured to” means that the limitations recited in the specification and/or the claims must be arranged in such a way to perform the recited function: “configured to” excludes structures in the art that are “capable of” being modified to perform the recited function but the disclosures associated with the art have no explicit teachings to do so. For example, a recitation of a “container configured to receive a fluid from structure X at an upper portion and deliver fluid from a lower portion to structure Y” is limited to systems where structure X, structure Y, and the container are all disclosed as arranged to perform the recited function. The recitation “configured to” excludes elements that may be “capable of” performing the recited function simply by virtue of their construction but associated disclosures (or lack thereof) provide no teachings to make such a modification to meet the functional limitations between all structures recited.

It is understood that the phraseology and terminology used herein is for description and should not be regarded as limiting. The use of “including,” “comprising,” or “having” and variations thereof herein is meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings. Further, “connected” and “coupled” are not restricted to physical or mechanical connections or couplings.

The previous detailed description is to be read with reference to the figures, in which like elements in different figures have like reference numerals. The figures, which are not necessarily to scale, depict some embodiments and are not intended to limit the scope of embodiments of the system.

It will be appreciated by those skilled in the art that while the system has been described above in connection with some embodiments and examples, the system is not necessarily so limited, and that numerous other embodiments, examples, uses, modifications and departures from the embodiments, examples and uses are intended to be encompassed by the claims attached hereto. The entire disclosure of each patent and publication cited herein is incorporated by reference, as if each such patent or publication were individually incorporated by reference herein. Various features and advantages of the system are set forth in the following claims.

What is claimed is:

1. A system comprising:
a fan module,
a power supply, and
a housing;
wherein the fan module is configured to create a vacuum to draw air through one or more intakes in the housing;
wherein the power supply is electrically connected to an AC electrical plug extending from a base portion of the housing; and
wherein the housing comprises a continuous gap that is configured as both an air intake and an air exhaust.

2. The system of claim 1,
wherein the fan module includes a single fan; and
wherein the housing includes an inner casing;
wherein the inner casing includes a first window and a second window configured to direct air being drawn by the vacuum created by the single fan.

3. The system of claim 2,
wherein the first window is configured to direct a first portion of the drawn air in a first direction over a first power supply component; and
wherein the second window is configured to direct a second portion of the drawn air in a second direction over a second power supply component.

4. The system of claim 3,
further including a third window; and
wherein the third window is configured to direct a portion of the drawn air in a third direction over a third power supply component.

5. The system of claim 2,
further including a middle heat spreader and a bottom heat spreader;
wherein the first window is a different size than the second window; and
wherein the different size is configured to create an airflow between the middle heat spreader and the bottom heat spreader.

6. The system of claim 2,
further including a heat sink; and
wherein the first window and the second window are each configured to direct the drawn air to different sides of the heat sink.

7. The system of claim 6,
further including a middle heat spreader and a bottom heat spreader;
wherein the first window includes a different size than the second window; and
wherein the different size is configured to create an airflow in a gap between the middle heat spreader and the bottom heat spreader.

8. The system of claim 6,
wherein the heat sink comprises a plurality of sink fins;
wherein one or more of the plurality of sink fins comprises a fin aperture.

9. The system of claim 8,
wherein the fin aperture is configured to enable drawn air to pass through.

10. The system of claim 6,
wherein the fan module is coupled to a center portion of the heat sink.

11. The system of claim 10,
wherein the different sides of the heat sink are distal from the center portion.

12. The system of claim 3,
wherein the housing further includes a top cover and a base;
wherein the top cover is configured to couple to the base; and
wherein the top cover and the base are configured to surround the inner casing.

13. The system of claim 12,
wherein a first sidewall intake path is formed adjacent the first window;
wherein a second sidewall intake path is formed adjacent the second window; and
wherein the first sidewall intake path and the second sidewall intake path are configured to direct the drawn air toward the top cover.

14. The system of claim 13,
further including a heat sink adjacent the top cover;
wherein the first sidewall intake path and the second sidewall intake path are configured to direct the drawn air over an outer parameter of the heat sink.

15. The system of claim 14,
wherein the heat sink includes a fan aperture;
wherein the fan aperture is configured to enable drawn air to pass from below the heat sink into the fan module.
